(19) United States
(12) Patent Application Publication
(10) Pub. No.: US 2015/0353359 A1
(43) Pub. Date: Dec. 10, 2015

(54) METHOD FOR PRODUCING CARBON NANOTUBES USING PROTEIN POLYMER

(71) Applicant: POSTECH ACADEMY-INDUSTRY FOUNDATION, Pohang-si (KR)

(72) Inventors: Kun Hong LEE, Pohang-si (KR); Hye Jin KIM, Seoul (KR); Sang Woo SEO, Seoul (KR); Jae Geun LEE, Daegu (KR)

(21) Appl. No.: 14/762,363

(22) PCT Filed: Sep. 12, 2013
(86) PCT No.: PCT/KR2013/008273

§ 371 Date: Jul. 21, 2015

(30) Foreign Application Priority Data
Jan. 23, 2013 (KR) 10-2013-0007419

(51) Int. Cl. C01B 31/02; C22C 38/00; C23C 16/26; B22F 1/00; B01J 23/745; B01J 35/00

(52) U.S. Cl. CPC C01B 31/0233; B01J 23/745; B01J 35/0013; C23C 16/26; B22F 1/0044; C22C 38/00

(57) ABSTRACT

The present invention relates to a method for producing carbon nanotubes using a protein polymer. The present invention provides a method for producing carbon nanotubes using metal nanoparticles in which substantially nonmetallic components are removed from a protein polymer containing metal. The synthesis of carbon nanotubes using the protein polymer as a catalyst enables acquisition of metal nanoparticles having desired sizes, and also adjustment of the sizes of the metal nanoparticles and consequently fine adjustment of diameters of the carbon nanotubes.

### TECHNICAL FIELD

The invention relates to the method of synthesizing the carbon nanotube using the protein, specifically, to the method of polymerizing protein including metal and manufacturing the carbon nanotube using the same as a catalyst.

### BACKGROUND ART

The electrical property of the carbon nanotube is determined by the diameter and chirality. Generally, as the mixed nanotubes having the various electrical properties are synthesized in the carbon nanotube synthesis process, it is important to selectively synthesize the nanotube having the desired electrical characteristics.

It has been well known that the diameter and chirality of nanotube are determined by metal nanoparticle which is used as catalyst. The vacuum evaporation method and sputtering method which has been used to obtain the catalyst up to now has a disadvantage that it is difficult to obtain the catalyst particle having a predetermined size. Also, self-assembly nanotemplate (Nanotemplate) or sol-gel method which is researched recently to obtain the catalyst has a disadvantage that it is difficult to obtain the particle less than 3 nm. To overcome these disadvantages, Republic of Korea Patent No. 962171, which is granted to Cheil Textile, discloses metal nanocatalyst for synthesis of carbon nanotube manufactured by the combustion of water-soluble metal catalyst derivative containing Co, Fe or Ni under the presence of the support element.

However, the demand for a method of controlling more precisely the size of carbon nanotube has been continued.

### DISCLOSURE

### Technical Problem

Accordingly, an object of the present invention is to provide method of controlling precisely the size of metal nanoparticle and using the same to precisely control the properties of carbon nanotube like diameter.

Another object of the present invention is to provide a method of controlling the size of the catalyst for manufacturing carbon nanotube.

Still another object of the present invention is to provide method of manufacturing catalyst for manufacturing carbon nanotube using protein, and synthesizing carbon nanotube having a predetermined size using the same.

### Technical Solution

In order to accomplish the above objects, the present invention provides method of manufacturing the carbon nanotube using the metal nanoparticle prepared by substantially removing the non-metallic component from the protein polymer comprising metal.

Although not theoretically limited, iron catalyst particle having a predetermined size can be synthesized by polymerization of a predetermined number of proteins including a predetermined number of metal atoms in itself like hemoprotein, and carbon nanotube having a predetermined diameter finally can be synthesized using the particle.

In the present invention, the protein comprising metal, which can be understood as a metalloprotein, maybe the haemoprotein having the iron-porphyrin, hemoglobin, cytochrome, catalase, myoglobin, hemocyanin(Cu²⁺), chlorophyll protein(Mg²⁺), carboxypeptidase(Zn²⁺), pyruvate kinase (K⁺, Mg²⁺), arginase (Mn²⁺), etc. The metallo protein may be a native protein or a synthetic protein.

In the present invention, the metal included in the protein is magnesium, vanadium, manganese, iron, nickel, copper, zinc, molybdenum, selenium etc.

In the present invention, the protein polymer is a polymer in which proteins including metal are combined by a protein cross-linking agent etc. The degree of the polymerization of the protein polymer is modulated by the number of metal atom included in the protein and the size of the carbon nanotube to be synthesized. Preferably, more than two proteins can be polymerized, more preferably 2100 proteins can be polymerized.

In the present invention, the protein polymer can be fractionated according to the size by fractionating unit like the chromatography.

In the present invention, while the protein polymer burns in the high temperature, non-metallic components are removed and the metallic components form the nanoparticles.

In the present invention, the term “non-metallic components are removed” means that the non-metallic components are removed to such an extent that metallic component can act as catalyst. Substantially, it means that preferably more than 90 wt % of non-metallic component, more preferably more than 95 wt %, much more than 99 wt % is removed.

In the present invention, the term “burns in the high temperature” means oxidizing at a temperature in which the non-metallic component can burn among oxygen. Preferably, it means oxidizing at 300˜900° C., for 15 min˜3 hr among the air.

In the present invention, the manufacture of the carbon nanotube can be accomplished by a step of supplying carbon gas at 600˜950° C. under the metal nanocatalyst existence. For example, the carbon nanotube can be synthesized with the atmospheric pressure thermo-chemistry vapor deposition. In the preferred embodiment, polymer is evenly spin-coated on the substrate, and the substrate is fixed inside a reactor, and then the reactor is closed to prevent a contact with the outside. Under the nitrogen atmosphere, temperature for synthesis is raised up to 600˜950° C. After temperature for synthesis is reached, supply of the nitrogen is stopped. And then, synthesis is began by the supply of 5˜40 slm of carbon gas, preferably 10˜30 slm. Carbon gas is supplied for 15 min˜2 hr of synthesis time, preferably, 30 min-1 hr. Methane, ethylene, acetylene, LPG, or its mixture can be used as the carbon gas.

According to one aspect of the present invention, the present invention provides a method of manufacturing the carbon nanotube using iron nanoparticle, wherein non-metallic component is substantially removed from the hemoglobin polymer.

According to one another aspect of the present invention, the present invention provides a method of manufacturing the metal nanoparticle, wherein the non-metallic component is substantially removed from the protein polymer comprising the metal.

According to one another aspect of the present invention, the present invention provides the metal nanoparticle characterized in that the non-metallic component is substantially removed from the protein polymer comprising the metal by oxidizing at high temperature.

### Advantageous Effects

In the carbon nanotube synthesis using protein polymer as a catalyst, the desired size of metal nanoparticle can be obtained. As a result, the diameter of the nanotube can be precisely controlled by controlling the size of particle.

### DESCRIPTION OF DRAWINGS

FIG. 1 illustrates the size exclusion chromatography result for hemoglobin polymer (green solid line), and standard material (dotted line).

FIG. 2 illustrates the result for separating of peaks of size exclusion chromatography with Gaussian.

FIG. 3 illustrates the scanning probe microscopy result for (a) nanoparticle formed from the polymer larger than the column limit, (b) nanoparticle formed the polymer consisting of 11 hemoglobins, respectively.

FIG. 4 illustrates the scanning probe microscope result for (a) carbon nanotube formed from the polymer larger than the column limit, (b) carbon nanotube formed from the polymer consisting of 11 hemoglobins, respectively.

FIG. 5 illustrate the number of iron atoms, the number of hemoglobin molecules, and the molecular weight of hemoglobin forming iron nanoparticles with diameters in the range of 0.7˜2.0 nm, respectively.

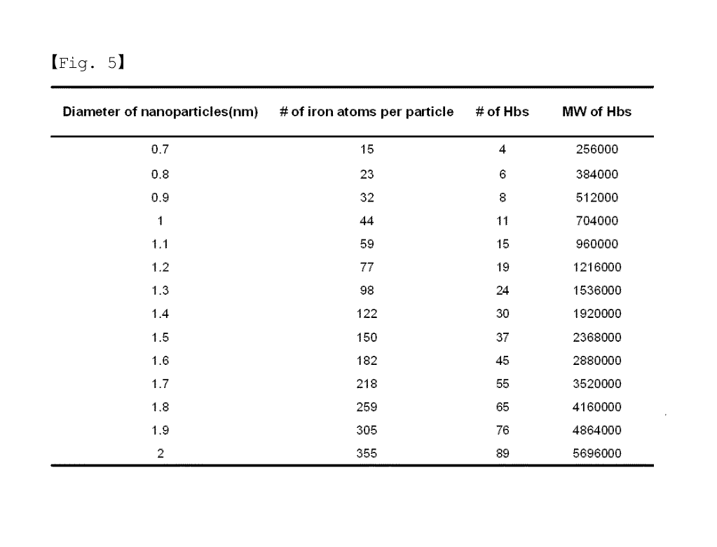

### BEST MODE

A better understanding of the present invention may be obtained via the following examples that are set forth to illustrate, but are not to be construed as limiting the present invention.

### Example

The carbon nanotube is synthesized using protein polymer manufactured by following steps. The Hemoglobin which is a representative protein including metal is polymerized using protein cross-linking agent like the glutaraldehyde.

Using the following equation (1),

$$N = \frac{πρ {D}^{3}}{6 M} {N}_{A}$$

It can be known that 1 nm iron nanoparticle consist of 44 iron atoms.

Since hemoglobin has 4 iron atoms per molecule, polymers consisting of 11 hemoglobins are synthesized and separated by the size exclusion chromatography. The separated polymers are deposited on the substrate and oxidized at high temperature to obtain the catalyst particle consisting of only iron atoms. The carbon nanotubes are synthesized with the catalyst particles on the substrate obtained.

1. Experimental Method.

a) Polymerization of Hemoglobin.

Using the 50 mM Tris adjusted at pH 8 as a buffer solution, 1 mM Hemoglobin solution and 25 mM glutaraldehyde solution were reacted at 4° C. for 30 min. After reaction was completed, 50 mM NaBH4 solution was added and reacted at 4° C. for 30 min to quench the reaction. After the reaction, the solution was dialyzed with a 10,000 MWCO Spectra/Por Biotech dialysis membrane for over 12 hours at 4° C. in 50 mM Tris-HCl buffer pH 8 to remove the excess cross-linking and quenching agents.

b) Separation of Hemoglobin Polymer (PolyHb) Using Size Exclusion Chromatography (SEC)

SEC was used to confirm the molecular weight of PolyHb and separate it. A Superose 6 10/300 GL (GE Healthcare) column was used with a mobile phase of 50 mM Tris buffer with 0.5 M MgCl₂. Blue dextrans (2,000 kDa), the thyroglobulin (669 kDa), the apoferritin (443 kDa), β-amylase (200 kDa), the and albumin (66 kDa) etc. was used as the standard material. The polymer of which molecular weight is confirmed was separated and was dialyzed in distilled water at 4° C. over 12 hr.

c) Catalyst Particle Formation

A Si wafer with a 300 nm oxide layer was treated with piranha solution (70 vol % H₂SO₄+30 vol % H₂O₂) for 30 min at 140° C., and then the fractionated PolyHb was deposited onto the substrates by spin coating. It was treated by oxidation at 800° C. for 5 min in order to leave only the iron atom on the substrate.

d) Carbon Nanotube Synthesis.

As-prepared substrates were placed in a 1 in. quartz tube and carbon nanotube was synthesized using the chemical vapor deposition. After the substrate being heated up to 750° C. under an argon (500 sccm) atmosphere, and then nanoparticles on the substrates were reduced in hydrogen (500 sccm), and then ethylene(100 sccm) was introduced for 10 min so as to synthesize carbon nanotube. After being cooled with only argon (500 sccm) to room temperature, the substrate was taken out.

2. Result

a) Size Exclusion Chromatography

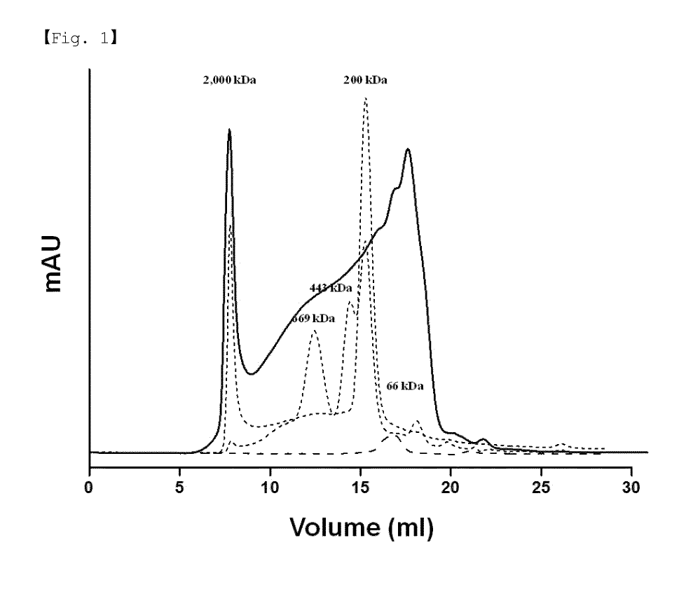

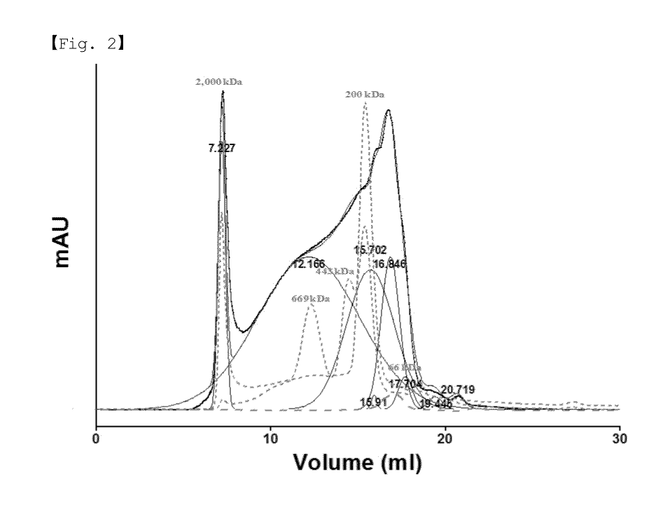

From the result of size exclusion chromatography of the FIG. 1, it can be seen that there are distinctive peaks at 8 ml and 17 ml, and broad peak in the range from 12 ml to 17 ml. By comparison with the result of the standard material, it can be known that the peak at 8 mL indicates the region of heavy PolyHb (h-PolyHb) which is larger than the MW limitation of the column and the peak at 17 mL indicates the region of non-reacted Hb. A broad peak from 12 ml to 17 ml is resolved using Gaussian analysis. As illustrated in FIG. 2, there is a broad peak at 12 mL, and the peak at 12 ml is present before that of the standard, thyroglobulin (669 kDa) on the chromatography. This indicates that the molecular weight of this region is larger than 669 KDa. It can be expected that PolyHb corresponding to the peak at 12 ml consist of 11 hemoglobins, because the molecular weight of hemoglobin is 64 kDa and the molecular weight of 11 hemoglobins is 704 kDa.

b) Catalyst Particle Formation

Polymer consisting of 11 hemoglobins (Red color region on the chromatography result) and polymer which is larger than the column limitation (blue color region on the chromatography result) are separated, and then catalyst particles are formed.

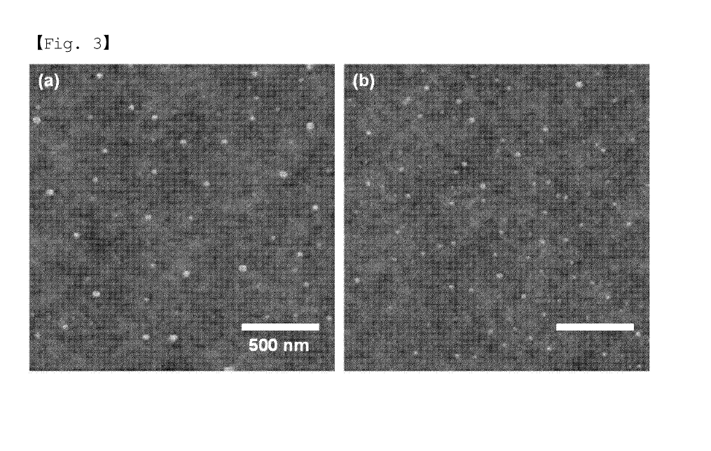

Diameter distributions are compared. After oxidation for removal of protein chain and cross-linked part from hemoglobin polymer, catalyst particles consisting of iron atoms are formed. It is confirmed by the scanning probe microscope that both of two polymers can form iron catalyst particles. (FIG. 3)

The diameter was measured and the distribution was confirmed, respectively. Then, the diameter distribution of the iron nanoparticles formed from the lager polymer is 2.60±0.74 nm, and the diameter distribution of the iron nanoparticles formed from the polymer consisting of 11 hemoglobins is 1.30±0.36 nm. The diameter distribution of the carbon nanotube synthesized from the polymer consisting of 11 hemoglobins is much narrower than that synthesized from the large polymer.

c) Synthesis of Carbon Nanotube.

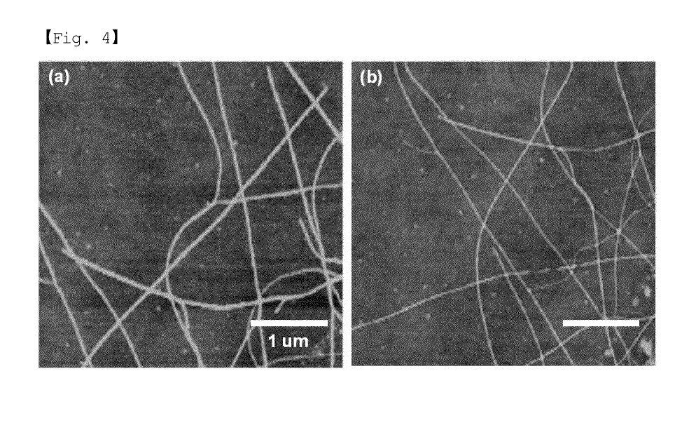

It could be confirmed by the scanning probe microscope that carbon nanotubes can be synthesized by chemical vapor deposition using iron nanoparticles obtained, respectively. (FIG. 4) Similarly, the diameter of each carbon nanotube was measured and the distribution was confirmed, respectively. The diameter distribution of the iron nanotubes formed from the lager polymer is 2.03±0.05 nm, and the diameter distribution of the iron nanotubes formed from the polymer consisting of 11 hemoglobins is 1.08±0.26 nm. The diameter distribution of the carbon nanotube synthesized from the polymer consisting of 11 hemoglobins is much narrower than that synthesized from the large polymer.

1. The method of manufacturing the carbon nanotube using the metal nanoparticle prepared by substantially removing the non-metallic component from the protein polymer comprising metal.

2. The method of manufacturing of claim 1, wherein one or more metal is selected from the group consisting of magnesium, vanadium, manganese, iron, nickel, copper, zinc, molybdenum, selenium.

3. The method of manufacturing of claim 1, wherein the protein is nature or synthetic protein.

4. The method of manufacturing of claim 1, wherein the protein polymer is combined by two or more proteins.

5. The method of manufacturing of claim 1, wherein the protein polymer is used after fraction according to the size.

6. The method of manufacturing of claim 1, wherein the non-metallic component is removed by oxidation of the polymer protein.

7. The method of manufacturing of claim 1, wherein the size of metal nanoparticle is controlled by the degree of protein.

8. The method of manufacturing of claim 1, wherein the protein polymer is coated onto the substrate and oxidized.

9. The method of manufacturing of claim 1, wherein the protein polymer is oxidized at the high temperature.

10. The method of manufacturing the carbon nanotube using iron nanoparticle prepared by substantially removing the non-metallic component from the hemoglobin polymer.

11. The method of manufacturing of claim 10, wherein diameter of carbon nanotube is controlled by the size of the protein polymer.

12. The method of manufacturing of claim 10, wherein carbon nanotube is obtained by the iron nanoparticle formation on the substrate and chemical vapor deposition or plasma chemical vapor deposition.

13. The method of manufacturing of claim 10, wherein the hemoglobin polymer is manufactured by polymerizing hemoglobins using protein binder.

14. The method of manufacturing the metal nanoparticle characterized in that the non-metallic components are substantially removed from the protein polymer comprising metal.

15. The method of manufacturing of claim 14, wherein non-metallic component is removed by oxidizing at the high temperature.

16. The method of manufacturing of claim 14, wherein the protein comprising metal is hemoglobin.

17. The method of manufacturing of claim 14, wherein the protein polymer is prepared by polymerization of 2˜100 proteins.

18. Metal nanoparticle characterized in that non-metallic component is substantially removed from the protein polymer comprising metal by oxidation at the high temperature.

19. Metal nanoparticle of claim 18, wherein the metal nanoparticle is iron nanoparticle.

20. Metal nanoparticle of claim 19, wherein the range of diameter of iron nanoparticle is 1.08±0.26 nm.
